(19) United States
(12) Patent Application Publication
(10) Pub. No.: US 2022/0223475 A1
(43) Pub. Date: Jul. 14, 2022

(54) SUBSTRATE PROCESSING METHOD AND SUBSTRATE PROCESSING SYSTEM

(71) Applicant: Tokyo Electron Limited, Tokyo (JP)

(72) Inventors: Hayato TANOUE, Kikuchi-gun, Kumamoto (JP); Yasutaka MIZOMOTO, Kikuchi-gun, Kumamoto (JP); Yohei YAMASHITA, Kikuchi-gun, Kumamoto (JP)

(21) Appl. No.: 17/595,658

(22) PCT Filed: May 11, 2020
(86) PCT No.: PCT/JP2020/018795

§ 371 Date: Nov. 22, 2021

(30) Foreign Application Priority Data
May 23, 2019 (JP) 2019-096791

(51) Int. Cl. H01L 21/78; H01L 21/304; H01L 21/67; H01L 21/306

(52) U.S. Cl. CPC H01L 21/78; H01L 21/304; H01L 21/30604; H01L 21/67063; H01L 21/67092

(57) ABSTRACT

A substrate processing method of processing a processing target substrate having a device formed on a front surface thereof includes preparing, in a first separation substrate on a side with the device and a second separation substrate on a side without the device separated from a device substrate, the second separation substrate; and bonding, by reusing the second separation substrate, the second separation substrate to a processing target substrate. A substrate processing system configured to process the processing target substrate having the device formed on the front surface thereof includes a bonding device configured to bond, in the first separation substrate on the side with the device and the second separation substrate on the side without the device separated from the device substrate, the second separation substrate to the processing target substrate by reusing the second separation substrate.

### TECHNICAL FIELD

The various aspects and embodiments described herein pertain generally to a substrate processing method and a substrate processing system.

### BACKGROUND

Patent Document 1 discloses a manufacturing method for a semiconductor device. In this manufacturing method, a rear surface of a wafer is ground and the wafer is divided in a state that a front surface of the wafer is fixed to a support member. Then, by separating the support member from the wafer, a plurality of semiconductor chips is obtained. The support member has a thickness larger than a thickness of the wafer after being ground. For example, meanwhile the thickness of the wafer ranges from about 700 μm to about 800 μm, the thickness of the support member is in a range of about 1 mm to about 2 mm.

Patent Document 2 discloses a method of manufacturing semiconductor chips. In this manufacturing method, a rear surface of a wafer is ground and the wafer is mounted to a dicing frame in a state that a support member is attached to a front surface of the wafer. Then, by dividing the wafer after separating the support member from the wafer, a plurality of semiconductor chips is obtained.

### PRIOR ART DOCUMENT

Patent Document 1: Japanese Patent Laid-open Publication No. 2012-146892

Patent Document 2: International Patent Publication No. 2003/049164

### DISCLOSURE OF THE INVENTION

### Problems to be Solved by the Invention

Exemplary embodiments provide a technique capable of reducing a cost in manufacturing a semiconductor device by bonding a substrate thinned by being separated to a processing target substrate to reuse the thinned substrate.

### Means for Solving the Problems

In an exemplary embodiment, a substrate processing method of processing a processing target substrate having a device formed on a front surface thereof includes preparing, in a first separation substrate on a side with the device and a second separation substrate on a side without the device separated from a device substrate, the second separation substrate; and bonding, by reusing the second separation substrate, the second separation substrate to a processing target substrate.

### Effect of the Invention

According to the exemplary embodiment, it is possible to reduce the cost in manufacturing the semiconductor device by bonding the substrate thinned by being separated to the processing target substrate to reuse the thinned substrate.

### BRIEF DESCRIPTION OF THE DRAWINGS

FIG. 1 is a plan view schematically illustrating a wafer processing system according to an exemplary embodiment.

FIG. 2 is a side view illustrating a schematic structure of a combined wafer.

FIG. 3A and FIG. 3B are side views schematically illustrating a first separation wafer and a second separation wafer.

FIG. 4 is a flowchart illustrating main processes of a wafer processing according to a first exemplary embodiment.

FIG. 5A to FIG. 5P are explanatory diagrams schematically illustrating individual processes of the wafer processing according to the first exemplary embodiment.

FIG. 6A to FIG. 6D are explanatory diagrams schematically illustrating some of the processes of the wafer processing according to the first exemplary embodiment, when viewed from the side.

FIG. 7 is a flowchart illustrating main processes of a wafer processing according to a second exemplary embodiment.

FIG. 8A to FIG. 8P are explanatory diagrams schematically illustrating individual processes of the wafer processing according to the second exemplary embodiment.

FIG. 9 is a plan view schematically illustrating a configuration of a dicing apparatus according to another exemplary embodiment.

FIG. 10 is a flowchart illustrating main processes of a wafer processing according to a third exemplary embodiment.

FIG. 11A to FIG. 11H are explanatory diagrams schematically illustrating individual processes of the wafer processing according to the third exemplary embodiment.

FIG. 12I to FIG. 12S are explanatory diagrams schematically illustrating individual processes of the wafer processing according to the third exemplary embodiment.

FIG. 13A to FIG. 13D are explanatory diagrams schematically illustrating some of processes of a wafer processing according to another exemplary embodiment.

### DETAILED DESCRIPTION

In a manufacturing process for a semiconductor device, a semiconductor wafer (hereinafter, simply referred to as a wafer) having a plurality of devices formed on a front surface thereof is thinned and diced in a state that a support substrate is attached to the front surface of the wafer. Then, by separating the support substrate from the wafer, semiconductor chips (hereinafter, simply referred to as chips) are produced.

The support substrate is temporarily attached to the wafer and separated from the wafer after a required processing is finished. Thus, from a viewpoint of cost reduction, it is desirable to use the support substrate repeatedly. In this regard, in order to further reduce the cost, the present inventors have come up with the idea of, when thinning the wafer, separating the wafer into a front side wafer having devices formed thereon and a rear side wafer to use the separated rear side wafer as a support wafer.

Further, in the methods described in the aforementioned Patent Documents 1 and 2, since the rear surface of the wafer is ground when thinning the wafer, it is difficult to reuse the separated rear side wafer, unlike in the present disclosure. Particularly, in Patent Document 1, since the thickness of the support substrate (support member) is larger than the thickness of the wafer, reusing the separated rear side wafer is not taken into account at all.

The present disclosure provides a technique of thinning a wafer by separating the wafer and reusing the separated wafer. Hereinafter, a wafer processing system as a substrate processing system and a wafer processing method as a substrate processing method according to exemplary embodiments will be described with reference to the accompanying drawings. In the present specification and the drawings, parts having substantially same functions and configurations will be assigned same reference numerals, and redundant description thereof will be omitted.

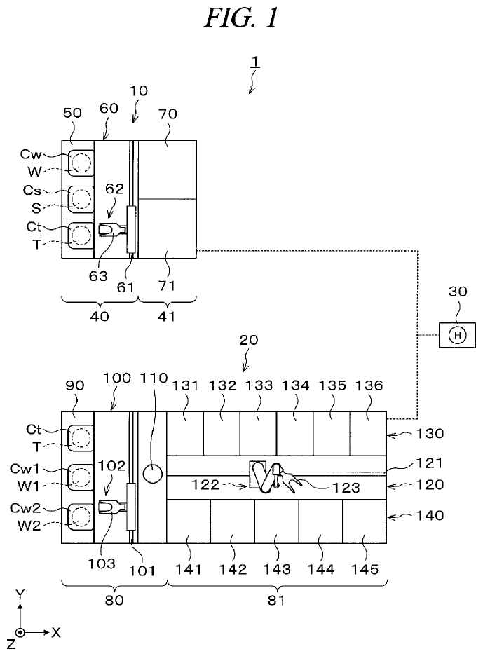

First, a configuration of the wafer processing system according to the present exemplary embodiment will be explained. FIG. 1 is a plan view schematically illustrating a configuration of a wafer processing system 1.

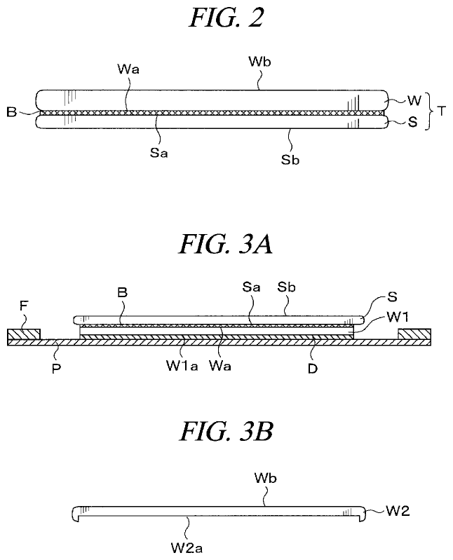

In the wafer processing system 1, as shown in FIG. 2, a combined wafer T is formed by bonding a device wafer W as a processing target substrate (device substrate) and a reuse wafer S reused as a support wafer to each other with an adhesive tape B as an adhesive layer therebetween, and a required processing is performed on the combined wafer T. Hereinafter, in the device wafer W, a surface bonded to the reuse wafer S with the adhesive tape B therebetween will be referred to as a front surface Wa, and a surface opposite to the front surface Wa will be referred to as a rear surface Wb. Likewise, in the reuse wafer S, a surface bonded to the device wafer W with the adhesive tape B therebetween will be referred to as a front surface Sa, and a surface opposite to the front surface Sa will be referred to as a rear surface Sb.

The device wafer W is a semiconductor wafer such as, but not limited to, a silicon substrate, and a device layer (not shown) including a plurality of devices is formed on the front surface Wa thereof.

The reuse wafer S is a wafer that supports the device wafer W, and it may be, for example, a silicon wafer. Further, a second separation wafer W2 separated from a previously processed device wafer W is used as the reuse wafer S, as will be described later.

In the wafer processing system 1 of the present exemplary embodiment, the device wafer W in the combined wafer T is separated. In the following description, the separated device wafer W on the front surface Wa side is referred to as a first separation wafer W1 as a first separation substrate, as shown in FIG. 3A, and the separated device wafer W on the rear surface Wb side is referred to as a second separation wafer W2 as a second separation substrate, as illustrated in FIG. 3B. The first separation wafer W1 has the device layer and is divided into a plurality of chips to be produced as products. The second separation wafer W2 is used as the reuse wafer S, as will be described later. In addition, a separated surface in the first separation wafer W1 is referred to as a separation surface W1a, that is, the separation surface W1a is a surface opposite to the front surface Wa. Further, a separated surface in the second separation wafer W2 is referred to as a separation surface W2a, that is, the separation surface W2a is a surface opposite to the rear surface Wb.

Further, in the wafer processing system 1, a die attach film (DAF) D and a dicing tape P are attached to the device wafer W (the first separation wafer W1) to fix the device wafer W to a dicing frame F, as shown in FIG. 3A, and a required processing is performed on the fixed device wafer W.

The die attach film D has adhesiveness on both sides thereof, and serves to bond first separation wafers W1 when stacking the first separation wafers W1 on top of each other. The dicing tape P has adhesiveness only on one surface, and the die attach film D is stuck to the corresponding one adhesive surface. The dicing frame F fixes the dicing tape P attached to the first separation wafer W1 with the die attach film D therebetween.

As depicted in FIG. 1, the wafer processing system 1 is equipped with a bonding apparatus 10 configured to bond the device wafer W and the reuse wafer S, and a wafer processing apparatus 20 configured to perform a required processing on the combined wafer T after being bonded. Further, an apparatus configuration in the wafer processing system 1 is not particularly limited. For example, a module of the bonding apparatus 10 and a module of the wafer processing apparatus 20 may be respectively disposed in other apparatuses.

In addition, the wafer processing system 1 is provided with a control device 30. The control device 30 is, for example, a computer having a CPU, a memory, or the like, and has a program storage (not shown). The program storage stores therein a program for controlling the wafer processing in the wafer processing system 1. Further, the program storage also stores therein a program for implementing the wafer processing in the wafer processing system 1 by controlling operations of various kinds of processing apparatuses and a driving system such as transfer devices. Furthermore, the program may be recorded on a computer-readable recording medium H and installed from the recording medium H to the control device 30.

The bonding apparatus 10 has a configuration in which a carry-in/out station 40 and a processing station 41 are connected as one body. The carry-in/out station 40 and the processing station 41 are arranged side by side from the negative X-axis side toward the positive X-axis side. In the carry-in/out station 40, cassettes Cw, Cs and Ct respectively capable of accommodating therein a plurality of device wafers W, a plurality of reuse wafers S, and a plurality of combined wafers T are carried to/from the outside, for example. The processing station 41 is equipped with various kinds of processing apparatuses configured to perform required processings on the device wafers W, the reuse wafers S and the combined wafers T.

A cassette placing table 50 is provided in the carry-in/out station 40. In the shown example, a plurality of, e.g., three cassettes Cw, Cs and Ct may be arranged on the cassette placing table 50 in a row in the Y-axis direction. Further, the number of the cassettes Cw, Cs and Ct placed on the cassette placing table 50 is not limited to the example of the present exemplary embodiment but may be selected as required.

In the carry-in/out station 40, a wafer transfer section 60 is provided adjacent to the cassette placing table 50 on the positive X-axis side of the cassette placing table 50. Provided in the wafer transfer section 60 is a wafer transfer device 62 configured to be movable on a transfer path 61 extending in the Y-axis direction. The wafer transfer device 62 is equipped with two transfer arms 63 configured to hold and transfer the device wafer W, the reuse wafer S and the combined wafer T. Each transfer arm 63 is configured to be movable in a horizontal direction and a vertical direction and pivotable around a horizontal axis and a vertical axis. Further, the configuration of the transfer arm 63 is not limited to the present exemplary embodiment, and various other configurations may be adopted. The wafer transfer device 62 is configured to be capable of transferring the device wafer W, the reuse wafer S and the combined wafer T to/from the cassettes Cw, Ct and Ct of the cassette placing table 50 and an adhesive layer forming module 70 and a bonding module 71 to be described later.

In the processing station 41, the adhesive layer forming module 70 and the bonding module 71 as a bonding device are arranged in the Y-axis direction on the positive X-axis side of the wafer transfer section 60. The number and the layout of these modules 70 and 71 are not limited to the example of the present exemplary embodiment but may be selected as required.

In the adhesive layer forming module 70, the adhesive tape B is attached to the front surface Wa of the device wafer W. Further, in the adhesive layer forming module 70, the adhesive tape B may be attached to the front surface Sa of the reuse wafer S. As the adhesive layer forming module 70, a commonly known apparatus may be used.

In the bonding module 71, the device wafer W and the reuse wafer S are bonded. For example, in the bonding module 71, the device wafer W and the reuse wafer S are pressed and bonded to each other with the adhesive tape B therebetween. As the bonding module 71, a commonly known apparatus may be used.

The wafer processing apparatus 20 has a configuration in which a carry-in/out station 80 and a processing station 81 are connected as one body. The carry-in/out station 80 and the processing station 81 are arranged from the negative X-axis side toward the positive X-axis side. In the carry-in/out station 80, cassettes Ct, Cw1 and Cw2 respectively capable of accommodating therein a plurality of combined wafers T, a plurality of first separation wafers W1 and a plurality of second separation wafers W are carried to/from the outside, for example. The processing station 81 is equipped with various kinds of processing apparatuses configured to perform required processings on the combined wafers T and the separation wafers W1 and W2.

Further, although the cassette Ct and the cassette Cw1 are provided separately, they may be the same one. That is, a single cassette may be used to accommodate both the combined wafers T before being processed and the first separation wafers W1 after being processed.

A cassette placing table 90 is provided in the carry-in/out station 80. In the shown example, a plurality of, for example, three cassettes Ct, Cw1 and Cw2 can be arranged on the cassette placing table 90 in a row in the Y-axis direction. Further, the number of the cassettes Ct, Cw1 and Cw2 placed on the cassette placing table 90 is not limited to the example of the present exemplary embodiment but may be selected as required.

In the carry-in/out station 80, a wafer transfer section 100 is provided adjacent to the cassette placing table 90 on the positive X-axis side of the cassette placing table 90. Provided in the wafer transfer section 100 is a wafer transfer device 102 configured to be movable on a transfer path 101 extending in the Y-axis direction. The wafer transfer device 102 is equipped with two transfer arms 103 configured to hold and transfer the combined wafer T, the separation wafer W1 and the separation wafer W2. Each transfer arm 103 is configured to be movable in the horizontal direction and the vertical direction and pivotable around a horizontal axis and a vertical axis. Further, the configuration of the transfer arm 103 is not limited to the present exemplary embodiment, and various other configurations may be adopted. The wafer transfer device 102 is configured to be capable of transferring the combined wafer T and the separation wafers W1 and W2 to/from the cassettes Ct, Cw1 and Cw2 of the cassette placing table 90 and a transition device 110 to be described later.

In the carry-in/out station 80, the transition device 110 configured to transfer the combined wafer T and the separation wafers W1 and W2 are provided adjacent to the wafer transfer section 100 on the positive X-axis side of the wafer transfer section 100.

In the processing station 81, a wafer transfer section 120, a first processing block 130, and a second processing block 140 are provided. The first processing block 130 is disposed on the positive Y-axis side of the wafer transfer section 120, and the second processing block 140 is disposed on the negative Y-axis side of the wafer transfer section 120.

A wafer transfer device 122 configured to be movable on a transfer path 121 extending in the X-axis direction is provided in the wafer transfer section 120. The wafer transfer device 122 is equipped with two transfer arms 123 configured to hold and transfer the combined wafer T, the separation wafer W1 and the separation wafer W2. Each transfer arm 123 is configured to be movable in the horizontal direction and the vertical direction and pivotable around a horizontal axis and a vertical axis. Further, the configuration of the transfer arm 123 is not limited to the present exemplary embodiment, and various other configurations may be adopted. The wafer transfer device 122 is configured to be capable of transferring the combined wafer T and the separation wafers W1 and W2 to/from the transition device 110 and various processing modules of the first processing block 130 and the second processing block 140.

In the first processing block 130, a modifying module 131, a separating module 132 as a separating device, a grinding module 133 as a grinding device, an inverting module 134, a cleaning module 135, and an etching module 136 as an etching device are arranged in the X-axis direction. The number and the layout of these modules 131 to 136 are not limited to the example of the present exemplary embodiment but may be selected as required.

In the modifying module 131, a modification layer is formed by radiating laser light to an inside of the device wafer W. As the laser light, one having a wavelength featuring transmissivity for the device wafer W is used. The modification layer is formed along the separation surface W1a of the first separation wafer W1 and the separation surface W2a of the second separation wafer W2. In addition, a configuration of the modifying module 131 is not particularly limited.

In the separating module 132, the device wafer W is separated into the first separation wafer W1 and the second separation wafer W2, starting from the modification layer formed in the modifying module 131. For example, in the separating module 132, while keeping the first separation wafer W1 and the second separation wafer W2 respectively attracted to and held by chucks (not shown), a blade having, for example, a wedge shape (not shown) is inserted to separate the first separation wafer W1 and the second separation wafer W2 along the separation surfaces W1a and W2a as a boundary. Thereafter, the first separation wafer W1 and the second separation wafer W2 are separated by moving the chucks away. In addition, a configuration of the separating module 132 is not particularly limited.

In the grinding module 133, the separation surface W1a of the first separation wafer W1 or the separation surface W2a of the second separation wafer W2 is ground. As the grinding module 133, a commonly known apparatus may be used.

In the inverting module 134, a front surface and a rear surface of the first separation wafer W1 or the second separation wafer W2 separated by the separating module 132 are inverted. As the inverting module 134, a commonly known apparatus may be used.

In the cleaning module 135, the separation surface W1a of the first separation wafer W1 or the separation surface W2a of the second separation wafer W2 is scrub-cleaned. As the cleaning module 135, a commonly known apparatus may be used.

In the etching module 136, the separation surface W1a of the first separation wafer W1 or the separation surface W2a of the second separation wafer W2 is etched. As the etching module 136, a commonly known apparatus may be used.

In the second processing block 140, an attaching module 141 as an attaching device, a dicing module 142 as a dicing device, a fixing module 143 as a fixing device, a separating module 144 as a separating device, and an adhesive layer removing module 145 are arranged in the X-axis direction. The number and the layout of these modules 141 to 145 are not limited to the example of the present exemplary embodiment but may be selected as required.

In the attaching module 141, a mounting processing of attaching the die attach film D to the separation surface W1a of the first separation wafer W1 is performed. As the attaching module 141, a commonly known apparatus may be used.

In the dicing module 142, the die attach film D or the first separation wafer W1 is diced by using laser lights. The laser light used for the dicing of the die attach film D and the laser light used for the dicing of the first separation wafer W1 are different in their specifications. A configuration of the dicing module 142 is not particularly limited. For example, different laser lights may be radiated from a single laser head, or the different laser lights may be radiated respectively from different laser heads.

In the fixing module 143, a mounting processing of attaching the dicing tape P to the first separation wafer W1 supported by the reuse wafer S and fixing the first separation wafer W1 to the dicing frame F is performed. As the fixing module 143, a commonly known apparatus may be used.

In the separating module 144, the reuse wafer S is separated from the first separation wafer W1. As the separating module 144, a commonly known apparatus may be used.

In the adhesive layer removing module 145, the adhesive tape B remaining on the front surface Wa of the first separation wafer W1 is removed by being separated. As the adhesive layer removing module 145, a commonly known apparatus may be used.

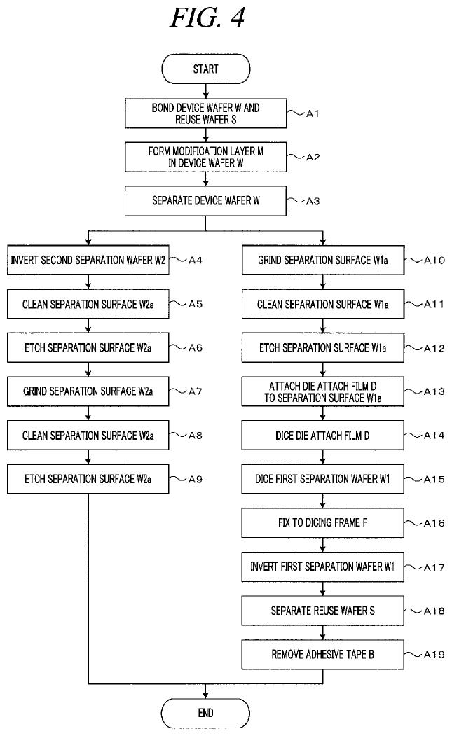

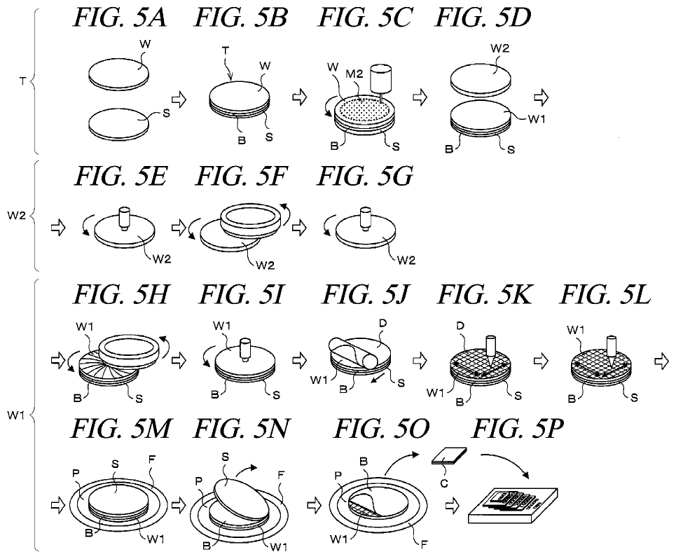

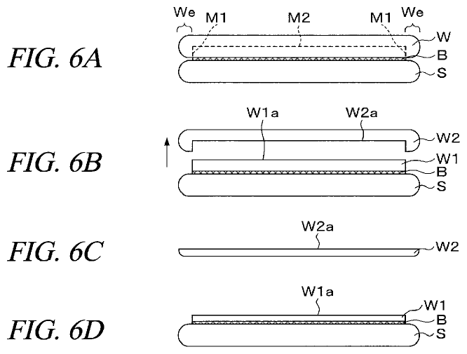

Now, a wafer processing according to a first exemplary embodiment performed in the wafer processing system 1 having the above-described configuration will be explained. FIG. 4 is a flowchart illustrating main processes of the wafer processing according to the first exemplary embodiment. FIG. 5A to FIG. 5P are explanatory diagrams schematically illustrating individual processes of the wafer processing according to the first exemplary embodiment. FIG. 6A to FIG. 6D are explanatory diagrams schematically illustrating some of the processes of the wafer processing according to the first exemplary embodiment, when viewed from the side.

First, in the bonding apparatus 10, the cassettes Cw and Cs respectively accommodating therein the plurality of device wafers W and the plurality of reuse wafers S as shown in FIG. 5A are placed on the cassette placing table 50 of the carry-in/out station 40.

Then, the device wafer W in the cassette Cw is taken out by the wafer transfer device 62 and transferred into the adhesive layer forming module 70. In the adhesive layer forming module 70, the adhesive tape B is attached to the front surface Wa of the device wafer W.

Next, the device wafer W is transferred into the bonding module 71 by the wafer transfer device 62. Then, the reuse wafer S in the cassette Cs is also taken out by the wafer transfer device 62 and transferred into the bonding module 71. In the bonding module 71, the device wafer W and the reuse wafer S are pressed and bonded with the adhesive tape B therebetween, as illustrated in FIG. 5B (process A1 of FIG. 4).

Then, the combined wafer T in which the device wafer W and the reuse wafer S are bonded to each other is transferred into the cassette Ct on the cassette placing table 50 by the wafer transfer device 62. In this way, the series of operations of the bonding processing in the bonding apparatus 10 are completed.

Thereafter, the cassette Ct accommodating therein the plurality of combined wafers T is carried out of the carry-in/out station 40 and transferred into the wafer processing apparatus 20. In the wafer processing apparatus 20, the cassette Ct is placed on the cassette placing table 90 of the carry-in/out station 80.

Subsequently, the combined wafer T in the cassette Ct is taken out by the wafer transfer device 102 and transferred into the transition device 110. Then, the combined wafer T is taken out of the transition device 110 by the wafer transfer device 122 and transferred into the modifying module 131. In the modifying module 131, laser light is radiated to an inside of the device wafer W, so that a modification layer M is formed as shown in FIG. 5C (process A2 of FIG. 4).

In the process A2, a peripheral modification layer M1 and an internal modification layer M2 are formed as the modification layer M, as shown in FIG. 6A. The peripheral modification layer M1 is formed in an annular shape and serves as a starting point when a peripheral portion We of the device wafer W is removed in edge trimming. The edge trimming is a process of suppressing the peripheral portion We of the device wafer W from having a sharply pointed shape (so-called knife edge shape) after the device wafer W is separated as will be described later. Further, the internal modification layer M2 serves as a starting point of separating and thinning the device wafer W. The internal modification layer M2 is formed along a plane direction of the device wafer W to extend from a central portion of the device wafer W to the peripheral modification layer Ml.

Thereafter, the combined wafer T is transferred into the separating module 132 by the wafer transfer device 102. In the separating module 132, the device wafer W in the combined wafer T is separated into the first separation wafer W1 and the second separation wafer W2, as illustrated in FIG. 5D (process A3 in FIG. 4).

In the process A3, the device wafer W is separated into the first separation wafer W1 and the second separation wafer W2, starting from the peripheral modification layer M1 and the internal modification M2, as illustrated in FIG. 6B. At this time, the peripheral portion We is integrated with the second separation wafer W2 and removed from the first separation wafer W1.

The first separation wafer W1 and the second separation wafer W2 separated in the separating module 132 are subjected to subsequent processings individually.

The second separation wafer W2 is transferred into the inverting module 134 by the wafer transfer device 122. In the inverting module 134, a front surface and a rear surface of the second separation wafer W2 are inverted (process A4 of FIG. 4). That is, in the inverting module 134, the separation surface W2a of the second separation wafer W2 is turned to face upwards.

Then, the second separation wafer W2 is transferred into the cleaning module 135 by the wafer transfer device 122. In the cleaning module 135, the separation surface W2a of the second separation wafer W2 is scrub-cleaned (process A5 of FIG. 4).

Then, the second separation wafer W2 is transferred into the etching module 136 by the wafer transfer device 122. In the etching module 136, the separation surface W2a of the second separation wafer W2 is wet-etched by an etching liquid, as shown in FIG. 5E (process A6 of FIG. 4). By this etching, the peripheral modification layer M1 and the internal modification layer M2 remaining on the separation surface W2a are removed.

Then, the second separation wafer W2 is transferred into the grinding module 133 by the wafer transfer device 122. In the grinding module 133, the separation surface W2a of the second separation wafer W2 is ground, as shown in FIG. 5F (process A7 of FIG. 4). By this grinding, a protruding outer peripheral portion of the separation surface W2a is removed, as shown in FIG. 6C.

Next, the second separation wafer W2 is transferred into the cleaning module 135 by the wafer transfer device 122. In the cleaning module 135, the separation surface W2a of the second separation wafer W2 is scrub-cleaned (process A8 of FIG. 4).

Then, the second separation wafer W2 is transferred into the etching module 136 by the wafer transfer device 122. In the etching module 136, the separation surface W2a of the second separation wafer W2 is wet-etched by an etching liquid, as illustrated in FIG. 5G (process A9 of FIG. 4). By this etching, grinding marks left on the separation surface W2a are removed.

Thereafter, the second separation wafer W2 after being subjected to all the required processings is transferred into the transition device 110 by the wafer transfer device 122, and then transferred into the cassette Cw2 on the cassette placing table 90 by the wafer transfer device 102.

The second separation wafer W2 after being subjected to the above-described processings has a thickness of, e.g., 400 μm to 700 μm. Thus, the second separation wafer W2 is reused as a reuse wafer S for a device wafer W to be processed next. That is, as shown in FIG. 5A and FIG. 5B, the second separation wafer W2 is bonded to the device wafer W to be processed next and functions as the support wafer.

As described above, in parallel with the processes A4 to A9 being performed on the second separation wafer W2, required processings are performed on the first separation wafer W1.

The first separation wafer W1 is transferred into the grinding module 133 by the wafer transfer device 122. In the grinding module 133, the separation surface W1a of the first separation wafer W1 is ground, as shown in FIG. 5H (process A10 of FIG. 4). By this grinding, the first separation wafer W1 is thinned to a required thickness, as illustrated in FIG. 6D.

Subsequently, the first separation wafer W1 is transferred into the cleaning module 135 by the wafer transfer device 122. In the cleaning module 135, the separation surface W1a of the first separation wafer W1 is scrub-cleaned (process A11 of FIG. 4).

Then, the first separation wafer W1 is transferred into the etching module 136 by the wafer transfer device 122. In the etching module 136, the separation surface W1a of the first separation wafer W1 is wet-etched by the etching liquid, as shown in FIG. 5I (process Al2 of FIG. 4). By this etching, the peripheral modification layer M1, the internal modification layer M2 and grinding marks remaining on the separation surface W1a are removed.

Next, the first separation wafer W1 is transferred into the attaching module 141 by the wafer transfer device 122. In the attaching module 141, the die attach film D is attached to the separation surface W1a of the first separation wafer W1, as shown in FIG. 5J (process A13 of FIG. 4).

Thereafter, the first separation wafer W1 is transferred into the dicing module 142 by the wafer transfer device 122. In the dicing module 142, by radiating laser light to the die attach film D, the die attach film D is diced, as shown in FIG. 5K (process A14 of FIG. 4).

Subsequently, by radiating laser light to the first separation wafer W1 in the same dicing module 142, the first separation wafer W1 is also diced, as shown in FIG. 5L (process A15 of FIG. 4).

Then, the first separation wafer W1 is transferred into the fixing module 143 by the wafer transfer device 122. In the fixing module 143, the dicing tape P is further attached to the die attach film D attached to the front surface Wa of the first separation wafer W1, as shown in FIG. 5M. Then, the first separation wafer W1 is fixed to the dicing frame F with the dicing tape P therebetween (process A16 of FIG. 4).

Afterwards, the first separation wafer W1 is transferred into the inverting module 134 by the wafer transfer device 122. In the inverting module 134, the front surface and the rear surface of the first separation wafer W1 (combined wafer T) are inverted (process A17 of FIG. 4).

Thereafter, the first separation wafer W1 is transferred into the separating module 144 by the wafer transfer device 122. In the separating module 144, the reuse wafer S is separated from the first separation wafer W1, as shown in FIG. 5N (process A18 of FIG. 4).

Then, the first separation wafer W1 is transferred into the adhesive layer removing module 145 by the wafer transfer device 122. In the adhesive layer removing module 145, the adhesive tape B is removed from the front surface Wa of the first separation wafer W1, as shown in FIG. 5O (process A19 of FIG. 4).

Thereafter, the first separation wafer W1 after being subjected to all the required processings is transferred into the transition device 110 by the wafer transfer device 122, and is then transferred into the cassette Cw1 on the cassette placing table 90 by the wafer transfer device 102. At this time, when the cassette Ct is empty, the first separation wafer W1 may be transferred into the cassette Ct. In this way, the series of processes of the wafer processing in the wafer processing system 1 are completed.

Through the above-described processes, chips C are manufactured. Then, the chips C are die-bonded at an outside of the wafer processing system 1, as shown in FIG. 5P.

According to the above-described first exemplary embodiment, the device wafer W is separated into the first separation wafer W1 and the second separation wafer W2. Then, the first separation wafer W1 is divided into the chips C to be produced as the products. Meanwhile, the second separation wafer W2 is bonded to a device wafer W to be processed next, and is reused as the reuse wafer S. Then, the reuse wafer S, which is the reused second separation wafer W2, can be repeatedly used for subsequent processings of the device wafer W.

Here, conventionally, a BG tape or a support wafer (not a reuse wafer but a newly prepared support wafer), for example, has been used as a support member for the device wafer W. In this case, a cost for preparing the support member is required. In the first exemplary embodiment, however, since the second separation wafer W2 is reused as the reuse wafer S for the device wafer W, the cost can be reduced.

Further, according to the first exemplary embodiment, since the device wafer W is subjected to the required processings after the device wafer W is bonded to the reuse wafer S, these processings can be performed stably. Further, the required processing such as etching can be performed on the thinned device wafer W (the first separation wafer W1) as well.

Further, according to the first exemplary embodiment, since the separation surface W1a of the first separation wafer W1 is ground in the process A10 after the device wafer W is separated into the first separation wafer W1 and the second separation wafer W2 in the process A3, the amount of the grinding can be reduced. That is, the grinding of the separation surface W1a can be simplified. Furthermore, if the first separation wafer W1 is etched to a required thickness in the process AU, the grinding in the process A10 may be omitted.

Further, in the above-described first exemplary embodiment, although the device wafer W is separated into the first separation wafer W1 and the second separation wafer W2 by performing the processes A2 and A3, the rear surface Wb of the device wafer W may be ground. In this case, the process A10 is performed instead of the processes A2 and A3 shown in FIG. 4, and the subsequent processes A11 to A19 are performed. Further, since the device wafer W is ground, the processes A4 to A9 are omitted. Additionally, in the wafer processing system 1, it may be also possible to omit the modifying module 131 and the separating module 132.

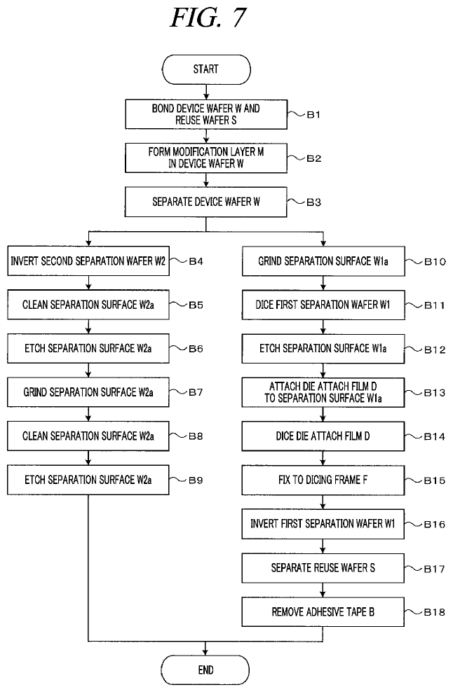

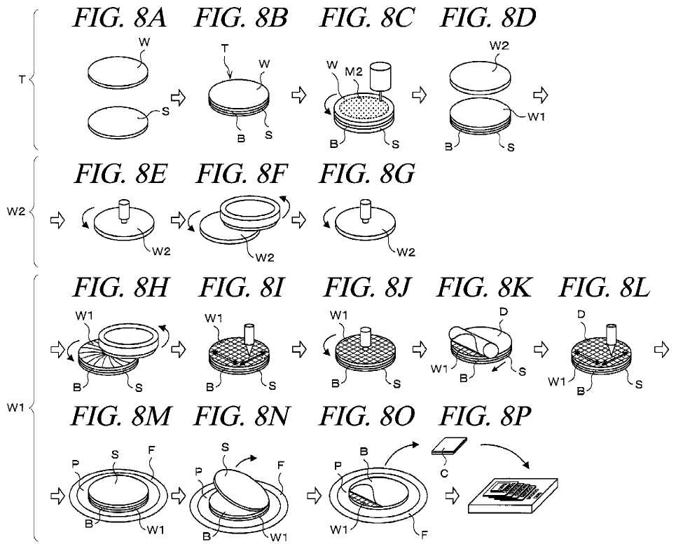

Now, a wafer processing according to a second exemplary embodiment will be discussed. FIG. 7 is a flowchart illustrating main processes of the wafer processing according to the second exemplary embodiment. FIG. 8A to FIG. 8P are explanatory diagrams schematically illustrating individual processes of the wafer processing according to the second exemplary embodiment. In the wafer processing according to the second exemplary embodiment as well, the wafer processing system 1 shown in FIG. 1 is used.

In the wafer processing of the second exemplary embodiment, processes B1 to B9 in FIG. 7, which are the same as the processes A1 to A9 of the wafer processing of the first exemplary embodiment, are performed in sequence. That is, the bonding of the device wafer W and the reuse wafer S in the process B1 shown in FIG. 8A and FIG. 8B, the formation of the modification layer M (the peripheral modification layer M1 and the internal modification layer M2) in the device wafer W in the process B2 shown in FIG. 8C, and the separation of the device wafer W in the process B3 shown in FIG. 8D are carried out sequentially.

Further, the processes B4 to B9 are performed on the second separation wafer W2 after being separated. That is, the inversion of the second separation wafer W2 in the process B4, the scrub-cleaning of the separation surface W2a in the process B5, and the etching of the separation surface W2a in the process B6 shown in FIG. 8E are performed sequentially. Thereafter, the grinding of the separation surface W2a in the process B7 shown in FIG. 8F, the scrub-cleaning of the separation surface W2a in the process B8, and the etching of the separation surface W2a in the process B9 shown in FIG. 8G are carried out sequentially. Then, the second separation wafer W2 after being subjected to all the required processings is transferred to the cassette Cw2.

As mentioned above, since the processes B1 to B9 are the same as the processes A1 to A9 of the first exemplary embodiment, description of the processes B1 to B9 will be omitted here. The wafer processing of the second exemplary embodiment is different from the wafer processing of the first exemplary embodiment in processing the separated first separation wafer W1, as will be described below. Specifically, a timing for performing the dicing of the first separation wafer W1 is different.

The first separation wafer W1 is transferred into the grinding module 133 by the wafer transfer device 122. In the grinding module 133, the separation surface W1a of the first separation wafer W1 is ground as shown in FIG. 8H (process 1310 of FIG. 7).

Then, the first separation wafer W1 is transferred into the dicing module 142 by the wafer transfer device 122. In the dicing module 142, laser light is radiated to the first separation wafer W1, so that the first separation wafer W1 is diced, as shown in FIG. 8I (process B11 of FIG. 7).

Subsequently, the first separation wafer W1 is transferred into the etching module 136 by the wafer transfer device 122. In the etching module 136, the separation surface W1a of the first separation wafer W1 is wet-etched by an etching liquid, as shown in FIG. 8J (process B12 of FIG. 7).

Next, the first separation wafer W1 is transferred into the attaching module 141 by the wafer transfer device 122. In the attaching module 141, the die attach film D is attached to the separation surface W1a of the first separation wafer W1, as shown in FIG. 8K (process 1313 of FIG. 7).

Subsequently, the first separation wafer W1 is transferred into the dicing module 142 by the wafer transfer device 122. In the dicing module 142, laser light is radiated to the die attach film D, so that the die attach film D is diced, as shown in FIG. 8L (process B14 of FIG. 7).

Then, the first separation wafer W1 is transferred into the fixing module 143 by the wafer transfer device 122. In the fixing module 143, the dicing tape P is further attached to the die attach film D which is attached to the front surface Wa of the first separation wafer W1, as shown in FIG. 8M. Then, the first separation wafer W1 is fixed to the dicing frame F via the dicing tape P (process B15 of FIG. 7).

Subsequently, the first separation wafer W1 is transferred into the inverting module 134 by the wafer transfer device 122. In the inverting module 134, the front and rear surfaces of the first separation wafer W1 (combined wafer T) are inverted (process B16 of FIG. 7).

Then, the first separation wafer W1 is transferred into the separating module 144 by the wafer transfer device 122. In the separating module 144, the reuse wafer S is separated from the first separation wafer W1, as shown in FIG. 8N (process B17 of FIG. 7).

Thereafter, the first separation wafer W1 is transferred into the adhesive layer removing module 145 by the wafer transfer device 122. In the adhesive layer removing module 145, the adhesive tape B is removed from the front surface Wa of the first separation wafer W1, as shown in FIG. 8O (process B18 of FIG. 7).

Afterwards, the first separation wafer W1 after being subjected to all the required processings is transferred to the cassette Cw1. Through the above-described processes, chips C are manufactured. Then, the chips C are die-bonded as shown in FIG. 8P at the outside the wafer processing system 1.

In the above-described second exemplary embodiment, the same effects as those of the first exemplary embodiment can be achieved.

Further, in the second exemplary embodiment as described above, the device wafer W is separated into the first separation wafer W1 and the second separation wafer W2 by performing the processes B2 and B3. However, the rear surface Wb of the device wafer W may be ground, the same as in the first exemplary embodiment. In this case, the process B10 is performed instead of the processes B2 and B3 shown in FIG. 7, and the subsequent processes B11 to B18 are performed. Further, since the device wafer W is ground, the processes B4 to B9 are omitted.

Now, a wafer processing according to a third exemplary embodiment will be described. In the wafer processings in the first and second exemplary embodiments described above, the dicing of the first separation wafer W1 is performed after the device wafer W bonded to the reuse wafer S is separated. In the third exemplary embodiment, however, the device wafer W before being bonded to the reuse wafer S is diced.

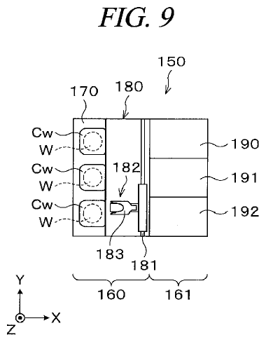

For the purpose, in performing the wafer processing according to the third exemplary embodiment, a dicing apparatus 150 shown in FIG. 9 is provided. The dicing apparatus 150 is provided in the wafer processing system 1 shown in FIG. 1. An operation of the dicing apparatus 150 is controlled by the control device 30.

As shown in FIG. 9, the dicing apparatus 150 has a configuration in which a carry-in/out station 160 and a processing station 161 are connected as one body. The carry-in/out station 160 and the processing station 161 are arranged from the negative X-axis side toward the positive X-axis side. In the carry-in/out station 160, cassettes Cw each capable of accommodating therein a plurality of device wafers W are carried to/from the outside, for example. The processing station 161 is equipped with various kinds of processing apparatuses configured to perform required processings on the device wafer W.

A cassette placing table 170 is provided in the carry-in/out station 160. In the shown example, a plurality of, e.g., three cassettes Cw may be arranged on the cassette placing table 170 in a row in the Y-axis direction. Further, the number of the cassettes Cw placed on the cassette placing table 170 is not limited to the example of the present exemplary embodiment but may be selected as required.

In the carry-in/out station 160, a wafer transfer section 180 is provided adjacent to the cassette placing table 170 on the positive X-axis side of the cassette placing table 170. Provided in the wafer transfer section 180 is a wafer transfer device 182 which is configured to be movable on a transfer path 181 extending in the Y-axis direction. The wafer transfer device 182 is equipped with two transfer arms 183 each of which is configured to hold and transfer the device wafer W. Each transfer arm 183 is configured to be movable in the horizontal direction and the vertical direction and pivotable around a horizontal axis and a vertical axis. Further, the configuration of the transfer arm 183 is not limited to the present exemplary embodiment, and various other configurations may be adopted. The wafer transfer device 182 is configured to be capable of transferring the device wafer W to/from the cassettes Cw of the cassette placing table 170 and a protective layer forming module 190, a dicing module 191 and a protective layer removing module 192 to be described later.

In the processing station 161, the protective layer forming module 190 as a protective layer forming device, the dicing module 191 as a dicing device, and the protective layer removing module 192 as a protective layer removing device are arranged in the Y-axis direction on the positive X-axis side of the wafer transfer section 180. Here, the number and the layout of these modules 190 to 192 are not limited to the example of the present exemplary embodiment, and may be selected as required.

In the protective layer forming module 190, a protective agent is spin-coated on the front surface Wa of the device wafer W to form a protective film as a protective layer. A commonly known apparatus may be used as the protective layer forming module 190.

In the dicing module 191, the device wafer W is diced by using laser light. A configuration of the dicing module 191 is the same as that of the dicing module 142 described above, and a commonly known apparatus may be used as the dicing module 191.

In the protective layer removing module 192, the protective film is removed from the front surface Wa of the device wafer W, and the front surface Wa is cleaned by spinning. In addition, a commonly known apparatus may be used as the protective layer removing module 192.

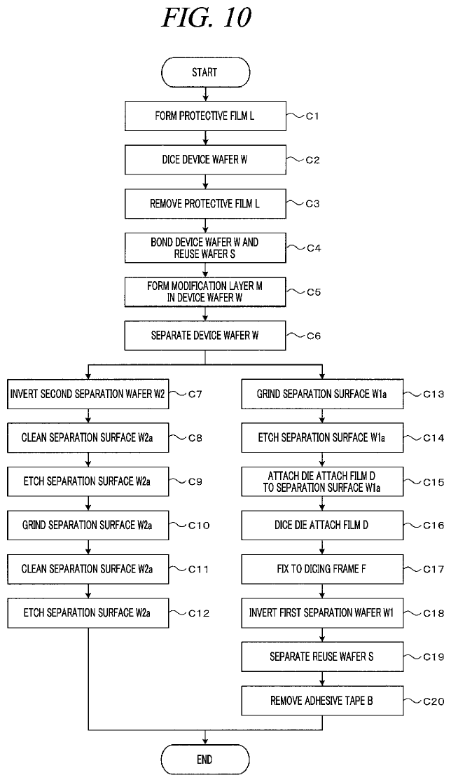

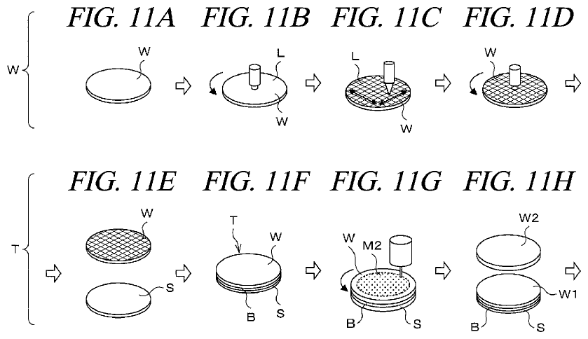

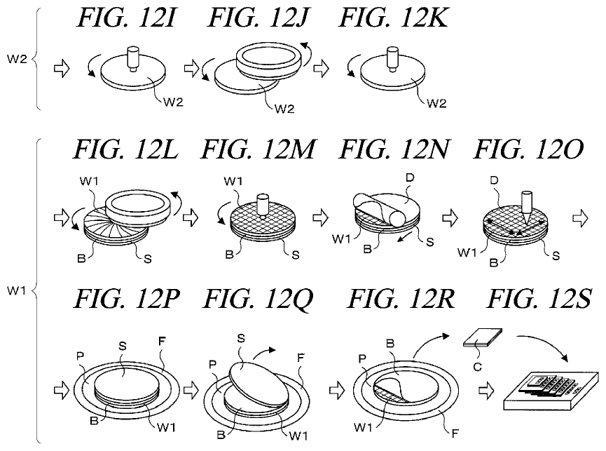

Now, the wafer processing according to the third exemplary embodiment performed in the wafer processing system 1 configured as described above will be explained. FIG. 10 is a flowchart showing main processes of the wafer processing according to the third exemplary embodiment. FIG. 11A to FIG. 12S are explanatory diagrams schematically illustrating individual processes of the wafer processing according to the third exemplary embodiment. FIG. 11A to FIG. 11H show the wafer processing up to a process of separating the device wafer W, and FIG. 12I to FIG. 12S show the wafer processing after the separating of the device wafer W.

First, in the dicing apparatus 150, the cassette Cw accommodating therein the plurality of device wafers W as shown in FIG. 11A is placed on the cassette placing table 170 of the carry-in/out station 160.

Next, the device wafer W in the cassette Cw is taken out by the wafer transfer device 182 and transferred into the protective layer forming module 190. In the protective layer forming module 190, the protective agent is spin-coated on the front surface Wa of the device wafer W, so that a protective film L is formed, as shown in FIG. 11B (process C1 of FIG. 10).

Thereafter, the device wafer W is transferred into the dicing module 191 by the wafer transfer device 182. In the dicing module 191, laser light is radiated to the device wafer W, so that the device wafer W is diced, as shown in FIG. 11C (process C2 of FIG. 10). In this dicing, the device layer formed on the device wafer W is protected by the protective film L.

Then, the device wafer W is transferred into the protective layer removing module 192 by the wafer transfer device 182. In the protective layer removing module 192, a solvent of the protective film L is supplied onto the front surface Wa of the device wafer W, so that the protective film L is removed, as shown in FIG. 11D (process C3 of FIG. 10).

Subsequently, the device wafer W is transferred into the cassette Cw of the cassette placing table 170 by the wafer transfer device 182. In this way, the series of processes of the dicing processing in the dicing apparatus 150 are completed.

Thereafter, the cassette Cw accommodating the plurality of device wafers W is carried out of the carry-in/out station 160, and is then transferred into the bonding apparatus 10. In the bonding apparatus 10, the cassette Cw is placed on the cassette placing table 50 of the carry-in/out station 40. Moreover, in the bonding apparatus 10, the cassette Cs accommodating the plurality of reuse wafers S as shown in FIG. 11E is also placed on the cassette placing table 50 of the carry-in/out station 40.

In the bonding apparatus 10, after the adhesive tape B is attached to the front surface Wa of the device wafer W in the adhesive layer forming module 70, the device wafer W and the reuse wafer S are pressed and bonded to each other with the adhesive tape B therebetween in the bonding module 71, as shown in FIG. 11F (process C4 of FIG. 10). Further, since the process C4 is the same as the process A1 of first exemplary embodiment, description thereof will be omitted here.

Thereafter, the cassette Ct accommodating therein the plurality of combined wafers T is carried out of the carry-in/out station 40 and transferred into the wafer processing apparatus 20. In the wafer processing apparatus 20, processes C5 to C12 of FIG. 10, which are the same as the processes A2 to A9 of the wafer processing of the first exemplary embodiment, are performed in sequence. That is, the formation of the modification layer M (the peripheral modification layer M1 and the internal modification layer M2) in the device wafer W in the process C5 shown in FIG. 11G, and the separation of the device wafer W in the process C6 shown in FIG. 11H are performed in sequence.

Further, the processes C7 to C12 are performed on the second separation wafer W2 after being separated. That is, the inversion of the second separation wafer W2 in the process C7, scrub-cleaning of the separation surface W2a in the process C8, and the etching of the separation surface W2a in the process C9 shown in FIG. 12I are performed sequentially. Subsequently, the grinding of the separation surface W2a in the process C10 shown in FIG. 12J, the scrub-cleaning of the separation surface W2a in the process C11, and the etching of the separation surface W2a in the process C12 shown in FIG. 12K are performed sequentially. Then, the second separation wafer W2 after being subjected to all the required processings is transferred to the cassette Cw2.

Here, as mentioned above, since the processes C5 to C12 are the same as the processes A2 to A9 of the first exemplary embodiment, redundant description thereof will be omitted.

The first separation wafer W1 is transferred into the grinding module 133 by the wafer transfer device 122. In the grinding module 133, the separation surface W1a of the first separation wafer W1 is ground as shown in FIG. 12L (process C13 of FIG. 10).

Then, the first separation wafer W1 is transferred into the etching module 136 by the wafer transfer device 122. In the etching module 136, the separation surface W1a of the first separation wafer W1 is wet-etched by the etching liquid, as shown in FIG. 12M (process C14 of FIG. 10).

Subsequently, the first separation wafer W1 is transferred into the attaching module 141 by the wafer transfer device 122. In the attaching module 141, the die attach film D is attached to the separation surface W1a of the first separation wafer W1, as shown in FIG. 12N (process C15 of FIG. 10).

Next, the first separation wafer W1 is transferred into the dicing module 142 by the wafer transfer device 122. In the dicing module 142, laser light is radiated to the die attach film D, so that the die attach film D is diced, as shown in FIG. 12O (process C16 of FIG. 10).

Then, the first separation wafer W1 is transferred to the fixing module 143 by the wafer transfer device 122. In the fixing module 143, the dicing tape P is further attached to the die attach film D which is attached to the front surface Wa of the first separation wafer W1, as shown in FIG. 12P. Then, the first separation wafer W1 is fixed to the dicing frame F with the dicing tape P therebetween (process C17 of FIG. 10).

Subsequently, the first separation wafer W1 is transferred into the inverting module 134 by the wafer transfer device 122. In the inverting module 134, the front and rear surfaces of the first separation wafer W1 (combined wafer T) are inverted (process C18 of FIG. 10).

Next, the first separation wafer W1 is transferred into the separating module 144 by the wafer transfer device 122. In the separating module 144, the reuse wafer S is separated from the first separation wafer W1, as shown in FIG. 12Q (process C19 of FIG. 10).

Then, the first separation wafer W1 is transferred into the adhesive layer removing module 145 by the wafer transfer device 122. In the adhesive layer removing module 145, the adhesive tape B is removed from the front surface Wa of the first separation wafer W1, as shown in FIG. 12R (process C20 of FIG. 10).

Thereafter, the first separation wafer W1 after being subjected to all the required processings is transferred into the cassette Cw1. Through the above-described processes, chips C are manufactured. Then, the chips C are die-bonded at the outside of the wafer processing system 1, as shown in FIG. 12S.

In the above-described third exemplary embodiment, the same effects as those of the first exemplary embodiment may be obtained.

Further, in the above-described third exemplary embodiment, although the device wafer W is separated into the first separation wafer W1 and the second separation wafer W2 by performing the processes C5 and C6, the rear surface Wb of the device wafer W may be ground, the same as in the first and second exemplary embodiments. In this case, the process C13 is performed instead of the processes C5 and C6 shown in FIG. 10, and the subsequent processes C14 to C20 are performed. Further, since the device wafer W is ground, the processes C7 to C12 are omitted.

In the above-described first to third exemplary embodiments, when the device wafer W is separated as shown in FIG. 6A to FIG. 6D, the peripheral portion We is integrated with the second separation wafer W2. However, the way how to separate the device wafer W is not limited thereto.

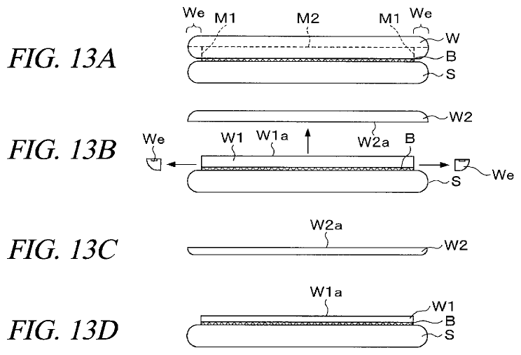

For example, as depicted in FIG. 13A, the peripheral modification layer M1 is formed up to an edge portion of the device wafer W within the device wafer W. If so, when the device wafer W is separated, the first separation wafer W1, the second separation wafer W2, and the peripheral portion We are individually separated, as illustrated in FIG. 13B. Even in such a case, the second separation wafer W2 shown in FIG. 13C can be reused, and chips C can be fabricated from the first separation wafer W1 shown in FIG. 13D.

In the above-described first to third exemplary embodiments, the adhesive tape B is used as the adhesive layer configured to bond the device wafer W and the reuse wafer S to each other. Without being limited thereto, however, an adhesive may be used.

In such a case, in the adhesive layer forming module 70, the adhesive is spin-coated on the front surface Wa of the device wafer W. A commonly known apparatus is used as the adhesive layer forming module 70.

Further, in the adhesive layer removing module 145, the adhesive remaining on the front surface Wa of the first separation wafer W1 is removed, and the front surface Wa is cleaned by spinning. In addition, a commonly known apparatus is used as the adhesive layer removing module 145.

In the above-described first to third exemplary embodiments, the second separation wafer W2 after being subjected to the required processings in the wafer processing system 1 is reused as the reuse wafer S to be bonded to the device wafer W. However, the reuse of the second separation wafer W2 is not limited thereto. By way of example, if the second separation wafer W2 after being subjected to the required processing has the thickness of 700 μm, reusing the second separation wafer W2 as a substrate for the device wafer W may also be possible.

Further, in the above-described first to third exemplary embodiments, the device wafer W as the processing target substrate is separated into the first separation wafer W1 and the second separation wafer W2, and the second separation wafer W2 is reused as the reuse wafer S. However, the reuse wafer S may be a wafer separated from a device wafer as another device substrate. For example, a pre-processing performed before the device wafer is transferred into the wafer processing system 1 includes a process of thinning the device wafer. In this thinning process, the device wafer is separated into a first separation wafer having a device formed thereon and a second separation wafer without having a device thereon. The second separation wafer thus separated may be reused as the reuse wafer S of the present exemplary embodiment.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system

10: Bonding apparatus

20: Wafer processing apparatus

71: Bonding module

132: Separating module

W: Device wafer

W1: First separation wafer

W2: Second separation wafer

1. A substrate processing method of processing a processing target substrate having a device formed on a front surface thereof, the substrate processing method comprising:
preparing, by separating the processing target substrate into a first separation substrate and a second separation substrate from a combined substrate in which the processing target substrate and a support substrate are bonded to each other, the second separation substrate, the first separation substrate having the device thereon, the second separation substrate having no device thereon; and
bonding the second separation substrate as the support substrate to a processing target substrate.

2. The substrate processing method of claim 1, further comprising:
grinding a separation surface of the second separation substrate separated from the processing target substrate; and
etching the separation surface of the ground second separation substrate.

3. The substrate processing method of claim 1, further comprising:
etching a separation surface of the first separation substrate separated from the processing target substrate;
dicing the etched first separation substrate;
fixing the diced first separation substrate to a dicing frame; and
separating the second separation substrate from the first separation substrate fixed to the dicing frame.

4. The substrate processing method of claim 3, further comprising:
attaching a die attach film to the separation surface of the etched first separation substrate; and
dicing the die attach film.

5. The substrate processing method of claim 3, further comprising:
attaching a die attach film to the separation surface of the diced first separation substrate; and
dicing the die attach film.

6. The substrate processing method of claim 1, further comprising:
forming a protective layer on the front surface of the processing target substrate before being bonded to the second separation substrate;
dicing the processing target substrate on which the protective layer is formed:
removing the protective layer from the diced processing target substrate;
bonding the second separation substrate as the support substrate to the processing target substrate from which the protective layer is removed;
separating the processing target substrate into the first separation substrate on a front surface side and the second separation substrate on a rear surface side;
etching a separation surface of the first separation substrate separated from the processing target substrate;
fixing the etched first separation substrate to a dicing frame; and
separating the second separation substrate from the first separation substrate fixed to the dicing frame.

7. The substrate processing method of claim 6, further comprising:
attaching a die attach film to the separation surface of the etched first separation substrate; and
dicing the die attach film.

8. The substrate processing method of claim 1, further comprising:
grinding the processing target substrate bonded to the second separation substrate;
etching a ground surface of the ground processing target substrate;
dicing the etched processing target substrate;
fixing the diced processing target substrate to a dicing frame; and
separating the second separation substrate from the processing target substrate fixed to the dicing frame.

9. The substrate processing method of claim 1,
wherein, in the separating of the processing target substrate into the first separation substrate and the second separation substrate, the second separation substrate is separated by being integrated with a peripheral portion of the processing target substrate, and
a separation surface of the second separation substrate separated from the processing target substrate is ground, and the protruding peripheral portion at an outer periphery of the separation surface is removed.

10. A substrate processing system configured to process a processing target substrate having a device formed on a front surface thereof, the substrate processing system comprising:
a bonding device configured to bond a second separation substrate as a support substrate to a processing target substrate, the second separation substrate being prepared by separating the processing target substrate into a first separation substrate and the second separation substrate from a combined substrate in which the processing target substrate and the support substrate are bonded to each other, the first separation substrate having the device thereon, the second separation substrate having no device thereon.

11. The substrate processing system of claim 10, further comprising:
a separating device configured to separate the processing target substrate into the first separation substrate on a front surface side and the second separation substrate on a rear surface side.

12. The substrate processing system of claim 10, further comprising:
a grinding device configured to grind a separation surface of the second separation substrate; and
an etching device configured to etch the separation surface of the second separation substrate.

13. The substrate processing system of claim 10, further comprising:
a dicing device configured to dice the first separation substrate;
a fixing device configured to fix the first separation substrate to a dicing frame; and
a separating device configured to separate the second separation substrate from the first separation substrate.

14. The substrate processing system of claim 10, further comprising:
an attaching device configured to attach a die attach film to a separation surface of the first separation substrate.

15. The substrate processing system of claim 10, further comprising:
a protective layer forming device configured to form a protective layer on the front surface of the processing target substrate before being bonded to the second separation substrate; and
a protective layer removing device configured to remove the protective layer from the processing target substrate.
